(19) United States
(12) Patent Application Publication
(10) Pub. No.: US 2026/0047375 A1
(43) Pub. Date: Feb. 12, 2026

(54) PLATE FLOW PATHS FOR GAS ACTIVATION, AND RELATED CHAMBER KITS, METHODS, AND PROCESSING CHAMBERS

(71) Applicant: Applied Materials, Inc., Santa Clara, CA (US)

(72) Inventors: Zhepeng CONG, San Jose, CA (US); Gracia Maria COSENZA LAGOS, San Jose, CA (US)

(21) Appl. No.: 18/800,947

(22) Filed: Aug. 12, 2024

(51) Int. Cl. H01L 21/67; H01L 21/02

(52) U.S. Cl. CPC H10P 72/0402; H10P 70/00

(57) ABSTRACT

The present disclosure relates to plate flow paths for gas activation, and related chamber kits, methods, and processing chambers. In one or more embodiments, a processing chamber includes a plate apparatus that includes one or more gas inlet openings in the plate apparatus on the first side of the processing volume, one or more gas outlet openings in the plate apparatus on a second side of the processing volume, and one or more gas flow channels. The one or more gas flow channels are operable to flow a gas through the plate apparatus between the one or more gas inlet openings and the one or more gas outlet openings. The one or more gas outlet openings are operable to inject the gas into the processing volume on the second side to flow the gas horizontally across the processing volume and to the one or more gas exhaust outlets.

### BACKGROUND

### Field

The present disclosure relates to plate flow paths for gas activation, and related chamber kits, methods, and processing chambers.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

However, gas flow can be limited with respect to adjustability and gas path length, which can negatively affect gas activation, deposition uniformity, element concentration, and/or performance of the manufactured device. For example, different gases can involve different gas path lengths and/or different temperatures for reliable activation.

Therefore, a need exists for improved process chamber components.

### SUMMARY

The present disclosure relates to plate flow paths for gas activation, and related chamber kits, methods, and processing chambers.

In one or more embodiments, a processing chamber includes a substrate support, one or more gas exhaust outlets on a first side of the processing volume, and a plate apparatus over the substrate support and at least partially defining a processing volume between the plate apparatus and the substrate support. The plate apparatus includes one or more gas inlet openings in the plate apparatus on the first side of the processing volume, one or more gas outlet openings in the plate apparatus on a second side of the processing volume, and one or more gas flow channels between the one or more inlet openings and the one or more outlet openings. The one or more gas flow channels are operable to flow a gas through the plate apparatus between the one or more gas inlet openings and the one or more gas outlet openings. The one or more gas outlet openings are operable to inject the gas into the processing volume on the second side to flow the gas horizontally across the processing volume and to the one or more gas exhaust outlets.

In one or more embodiments, a plate apparatus includes a first plate and a second plate. The first plate includes one or more inlet openings and one or more outlet openings therein. The second plate is sized and shaped for disposition on the first plate to define one or more flow channels between the first plate and the second plate. The first plate and the second plate respectively include opaque particles suspended in transparent quartz.

In one or more embodiments, a method of substrate processing includes heating a substrate support in a processing volume of a processing chamber, and flowing one or more process gases between the substrate support and a plate apparatus spaced from the substrate support. The flowing of the one or more process gases includes flowing a first gas flow through a sidewall of the processing chamber on an inject side of the processing volume, into the processing volume, and over a substrate positioned on the substrate support. The flowing of the one or more process gases includes flowing a second gas flow through the sidewall of the processing chamber on an exhaust side of the processing volume, flowing the second gas flow through the plate apparatus from the exhaust side and to the inject side, and flowing the second gas flow out of the plate apparatus and into the processing volume on the inject side, and over the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional view of a processing chamber, according to one or more embodiments.

FIG. 2 is a partial schematic side cross-sectional view of the processing chamber shown in FIG. 1, according to one or more embodiments.

FIG. 3 is an enlarged view of the plate apparatus in the processing chamber shown in FIG. 2, according to one or more embodiments.

FIG. 4 is a schematic partial perspective view of the plate apparatus shown in FIG. 3, according to one or more embodiments.

FIG. 5 is a schematic partial top view of a plate apparatus, according to one or more embodiments.

FIG. 6 is a schematic partial side cross-sectional view of the plate apparatus shown in FIG. 5, according to one or more embodiments.

FIG. 7 is an enlarged cross-sectional view of a plate apparatus in the processing chamber, according to one or more embodiments.

FIG. 8 is a schematic perspective partial view of the first liner shown in FIGS. 1 and 2, according to one or more embodiments.

FIG. 9 is a schematic top partial view of the first liner shown in FIG. 8, according to one or more embodiments.

FIG. 10 is a schematic top partial view of the second liner shown in FIGS. 1 and 2, according to one or more embodiments.

FIG. 11 is a schematic perspective partial view of an inject block shown in FIGS. 1-3, according to one or more embodiments.

FIG. 12 is a schematic partial perspective view of part of the chamber kit, according to one or more embodiments.

FIG. 13 is a schematic partial perspective view of the liner and blocks of the chamber kit, according to one or more embodiments.

FIG. 14 is a schematic top view of the plate apparatus supported on the first liner, according to one or more embodiments.

FIG. 15 is a schematic block diagram view of a method of substrate processing for semiconductor manufacturing, according to one or more embodiments.

FIG. 16 is a schematic partial top view of a plate apparatus, according to one or more embodiments.

FIG. 17 is a schematic partial top view of a plate apparatus, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to plate flow paths for gas activation, and related chamber kits, methods, and processing chambers.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

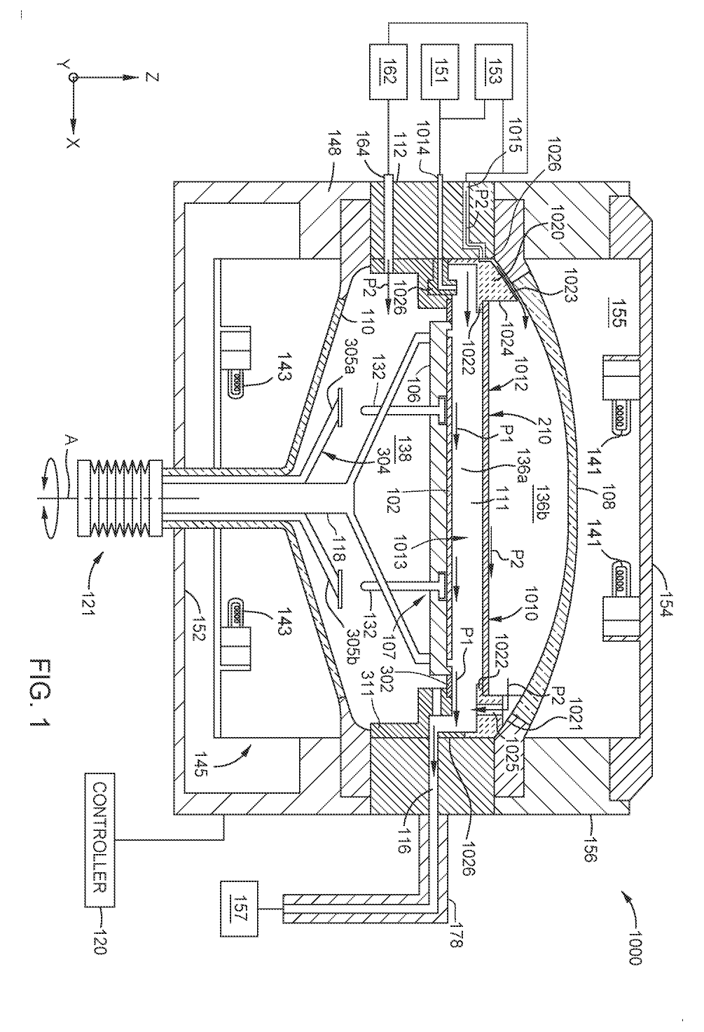

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper plate 108 (such as an upper window and/or an upper dome), a lower plate 110 (such as a lower window and/or a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper plate 108 and the lower plate 110. The substrate support 106 includes a support face that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

A chamber kit 1010 includes a plate apparatus 210. The plate apparatus 210 includes an isolation plate 111 having a first outer face 1012 and a second outer face 1013 opposing the first outer face 1012. The second outer face 1013 faces the substrate support 106. The chamber body includes a first liner 1020 and a second liner 311. The second liner 311 is disposed below the first liner 1020. The pre-heat ring 302 is supported on a ledge of the second liner 311. The first liner 1020 includes a curved section 1021 (e.g., an annular section). One or more inlet openings 1023 extending to an inner surface 1024 of the curved section 1021 are on a first side of the first liner 1020, and one or more second outlet openings 1025 are on a second side of the first liner 1020. The one or more inlet openings 1023 can be between the first liner 1020 and the upper plate 108. The first liner 1020 includes one or more ledges 1022 sized and shaped to support an outer region of the plate apparatus 210.

In the embodiment shown in FIG. 1, a lowermost end of the plate apparatus 210 is aligned above a lowermost end of the first liner 1020. In one or more embodiments, as shown in FIG. 1, the lowermost end of the plate apparatus 210 is part of the second outer face 1013, and the lowermost end of the first liner 1020 is part of an extension.

At least part of the plate apparatus 210 is in the shape of a disc, and at least part of the curved section 1021 is in the shape of a ring. It is contemplated, however, that the plate apparatus 210 and/or the curved section 1021 can be in the shape of a rectangle, or other geometric shapes. The plate apparatus 210 at least partially fluidly isolates an upper portion 136b of an internal volume from a lower portion 136a of the internal volume. The lower portion 136a is a processing volume. The plate apparatus 210 at least partially defines the processing volume between the plate apparatus 210 and the substrate support 106.

The flow module 112 (which can define at least part of one or more sidewalls of the processing chamber 1000) includes one or more first gas inlets 1014 in fluid communication with the lower portion 136a (e.g., the processing volume) of the internal volume. The flow module 112 includes one or more second inlet openings 1015 in fluid communication with the upper portion 136b of the internal volume. The one or more first gas inlets 1014 are in fluid communication with one or more flow gaps between the first liner 1020 and the second liner 311. One or more inject blocks 1026 having one or more flow openings formed therein can be disposed in one or more flow gaps between the first liner 1020 and the second liner 311. The one or more second inlet openings 1015 are in fluid communication with the one or more inlet openings 1023 above the first liner 1020. The first gas inlets 1014 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases and/or etching gases supplied using the one or more cleaning gas sources 153 can include one or more of hydrogen and/or chlorine (such as hydrochloric acid (HCl)). In one or more embodiments, the one or more process gases include silicon hydrides (such as one or more silanes and/or one or more chlorinated silanes), germanium (such as germane (GeH₄)), boron (such as diborane (B₂H₆)), and/or phospine (PH₃) .

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

During a deposition operation (e.g., an epitaxial growth operation), the one or more process gases P1 flow through the one or more first gas inlets 1014, through the one or more gaps, and into the lower portion 136a to flow horizontally over the substrate support 106 and the substrate 102 and to the one or more gas exhaust outlets 116. During the deposition operation, one or more purge gases P2 flow through the one or more second inlet openings 1015, through the one or more inlet openings 1023 of the first liner 1020, and into the upper portion 136b. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through exhaust gaps between the first liner 1020 and the second liner 311, and through the one or more gas exhaust outlets 116. The one or more purge gases P2 are exhausted through the one or more second outlet openings 1025, through the same exhaust gaps between the first liner 1020 and the second liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases can be supplied to the purge volume 138 (through the plurality of purge gas inlets 164) during the deposition operation, and exhausted from the purge volume 138.

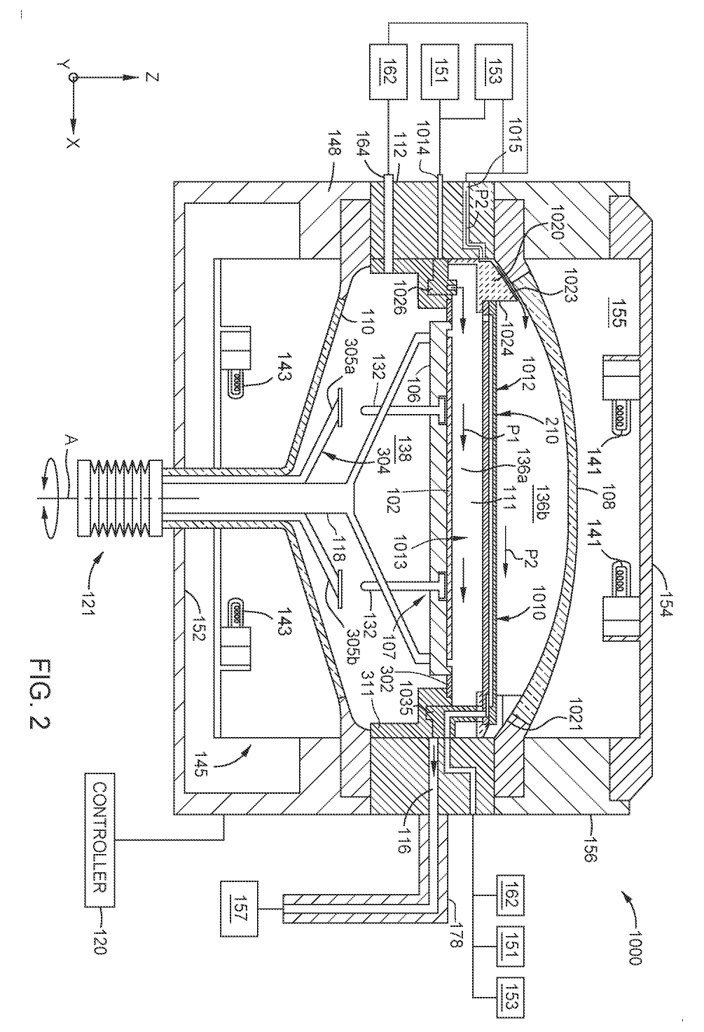

FIG. 2 is a partial schematic side cross-sectional view of the processing chamber 1000 shown in FIG. 1, according to one or more embodiments. The cross-sectional view shown in FIG. 2 is taken along a different plane (e.g., a different angle) relative to the cross-sectional view shown in FIG. 1.

FIG. 3 is an enlarged view of the plate apparatus 210 in the processing chamber 1000 shown in FIG. 2, according to one or more embodiments.

FIGS. 2 and 3 are described together. The plate apparatus 210 includes one or more inlet openings 211 (e.g., one or more gas inlet openings), one or more outlet openings 213 (e.g., one or more gas outlet openings), and one or more flow channels 212 (e.g., one or more gas flow channels) between the one or more inlet openings 211 and the one or more outlet openings 213. The present disclosure contemplates that one or more flow protrusions 214 can be coupled to the plate apparatus 210, and the one or more inlet openings 211 can extend through the one or more flow protrusions 214. In one or more embodiments, the plate apparatus 210 includes a first plate 215 having the one or more inlet openings 211 and the one or more outlet openings therein 213, and a second plate 216 sized and shaped for disposition on the first plate 215 to define the one or more flow channels 212 between the first plate 215 and the second plate 216. The second plate 216 can rest on the first plate 215. The second plate 216 can be bonded (such as diffusion bonded), fused, and/or welded to the first plate 215. The first plate 215 and the second plate 216 can be integrally formed. For example, the plate apparatus 210 can be machined from a single plate.

At least part of the plate apparatus 210 includes a transparent material (such as transparent quartz), an opaque material (such as opaque quartz (e.g. white quartz, or grey quartz; and/or black quartz), silicon carbide (SiC), and/or graphite coated with SiC), and/or one or more ceramics (such as alumina (aluminum oxide (Al₂O₃)), aluminum nitride (AlN), silicon nitride (Si₃N₄), Boron Nitride (BN), and/or Boron Carbide (B₄C))). In one or more embodiments, the plate apparatus 210 includes a transparent material (such as quartz) and opaque particles (such as SiC particles and/or Si particles) suspended in the transparent material. For example, the first plate 215 and/or the second plate 216 can be formed of the transparent material and opaque particles suspended in the transparent material.

During operation (e.g., a deposition operation), the flowing of one or more process gases P1 includes flowing a first gas flow F1 through a sidewall of the processing chamber 1000 on an inject side 1051 of the processing volume 136a, into the processing volume 136a, and over the substrate 102 positioned on the substrate support 106. The flowing of one or more process gases P1 also includes flowing a second gas flow F2 through the sidewall of the processing chamber 1000 on an exhaust side 1052 of the processing volume 136a. The second gas flow F2 flows through the plate apparatus 210 from the exhaust side 1052 and to the inject side 1051. The second gas flow F2 flows out of the plate apparatus 210 and into the processing volume 136a on the inject side 1051, and over the substrate 102. One or more inject blocks 1035 having one or more flow openings formed therein can be disposed in the one or more exhaust gaps between the first liner 1020 and the second liner 311. The one or more inject blocks can supply the second gas flow F2 to the plate apparatus 210.

The openings 211, 212, 213 can extend the heating path length of the second gas flow F2 relative to the first gas flow F1, facilitating using different gases having different activation temperatures. The second gas flow F2 can mix with the first gas flow F1 in the processing volume 136a. The present disclosure contemplates that different gases can be supplied to different inlet openings 211. In one or more embodiments, the second gas flow F2 includes one or more of dichlorosilane, hydrogen, and/or phosphine. In one or more embodiments, the first gas flow F1 includes hydrochloric acid, germane, and/or diborane.

The first liner 1020 includes a recessed portion 1031 and one or more openings 1032 in the recessed portion 1031. The one or more openings 1032 are sized and shaped to at least partially align with the one or more inlet openings 211 of the plate apparatus 210. The one or more ledges 1022 of the liner 1020 are disposed radially inwardly of the recessed portion 1031.

The various openings (e.g., inlet openings, flow channels, and outlet openings) described herein are shown as holes and recesses. Other opening structures and shapes are contemplates. For example, the flow channels 212 can be part of tubes that are coupled (e.g., welded) to the first plate 215 and/or the second plate 216. As another example, the flow channels 212 can be spaces positioned between respective plates 215, 216 and filler tubes welded to the respective plates 215, 216. As a further example, the flow channels 212 can be holes machined into a plate.

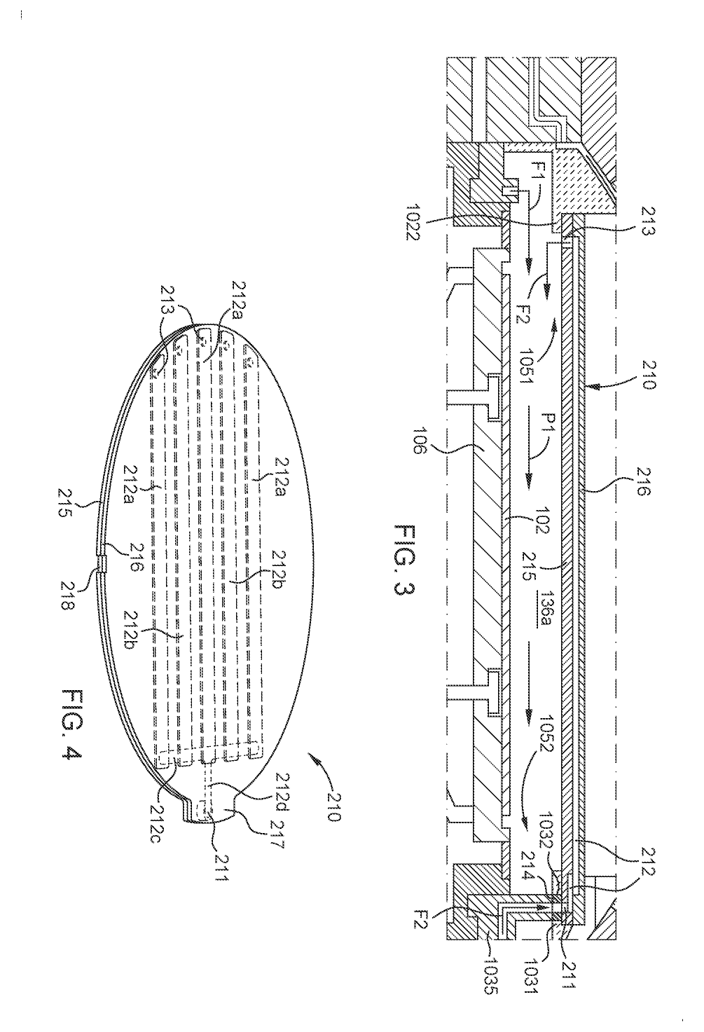

FIG. 4 is a schematic partial perspective view of the plate apparatus 210 shown in FIG. 3, according to one or more embodiments.

The one or more inlet openings 211 of the plate apparatus 210 are in a flange section 217 of the plate apparatus 210. The flange section 217 is sized and shaped to extend over the recessed portion 1031 of the first liner 1020. The plate apparatus 210 includes a locating opening 218 in an outer edge of the plate apparatus 210. Transfer equipment (such as heads of lift pins) can extend through the locating opening 218 the plate apparatus 210 is lowered onto the upper liner 1020.

The one or more flow channels 212 include a plurality of flow channels 212 spaced from each other. In one or more embodiments, the plurality of flow channels 212 are in fluid communication with a single inlet opening 211 of the one or more inlet openings 211. The flow channels 212 can be formed in the first plate 215 and/or the second plate 216. For example one or more flow channels 212 can include a first set of flow channels 212a (e.g., a first set of recesses) in the first plate 215 and a second set of flow channels 212b (e.g., a second set of recesses) in the second plate 216. In one or more embodiments, the first set of flow channels 212a and the second set of flow channels 212b are disposed in an alternating arrangement. In one or more embodiments, the first and second sets flow channels 212a, 212b are in fluid communications with a common plenum 212c and a flow channel 212d extending between the common plenum 212c and the one or more inlet openings 211.

FIG. 5 is a schematic partial top view of a plate apparatus 510, according to one or more embodiments. The plate apparatus 510 includes one or more aspects, features, components, operations, and/or properties of the plate apparatus 210 shown in FIGS. 1-4. The plate apparatus 510 can be used in place of the plate apparatus 210 shown in FIGS. 1-4.

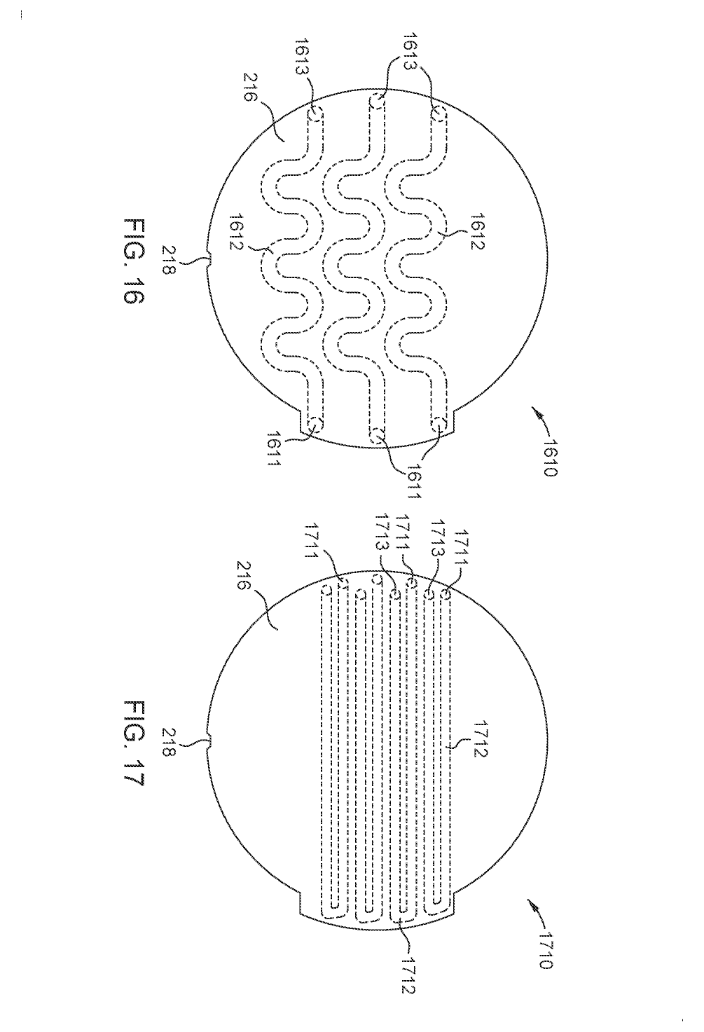

The flow channels 212 are fluidly connected respectively to a plurality of inlet openings 211. As shown in FIGS. 4 and 5, the one or more flow channels 212 can be linear (such as straight). Other configurations are contemplated for the one or more flow channels 212. For example, at least part of the respective flow channel(s) 212 can be curved (such as in the shape of a sinusoidal wave and/or a snake path) or angled (such as jagged, for example in the shape of a zig-zag path). FIG. 16 shows an example of a zig-zag path.

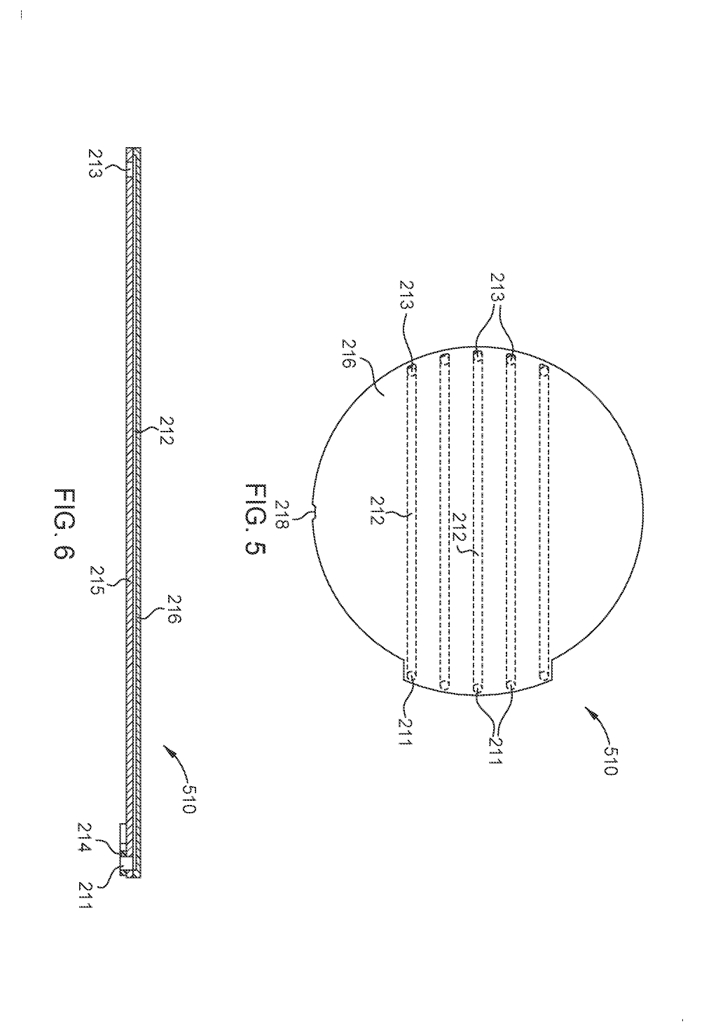

FIG. 6 is a schematic partial side cross-sectional view of the plate apparatus 510 shown in FIG. 5, according to one or more embodiments.

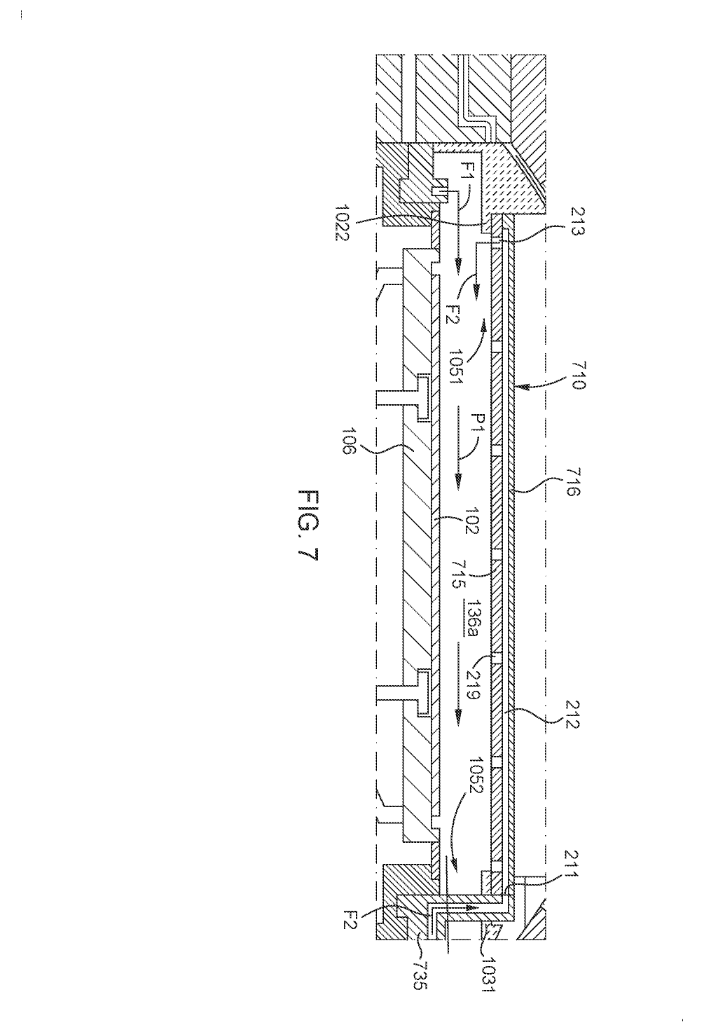

FIG. 7 is an enlarged cross-sectional view of a plate apparatus 710 in the processing chamber 1000, according to one or more embodiments. The plate apparatus 710 includes one or more aspects, features, components, operations, and/or properties of the plate apparatus 210 shown in FIGS. 1-4. The plate apparatus 710 can be used in place of the plate apparatus 210 shown in FIG. 3.

The plate apparatus 710 includes a second plate 716 spaced from a first plate 715 to define the one or more inlet openings 211 between the plates 715, 716. The first plate 715 of the plate apparatus 710 can include one or more second outlet openings 219 extending between the one or more flow channels 212 and the processing volume 136a. The first plate 715 can function as a showerhead.

FIG. 8 is a schematic perspective partial view of the first liner 1020 shown in FIGS. 1 and 2, according to one or more embodiments.

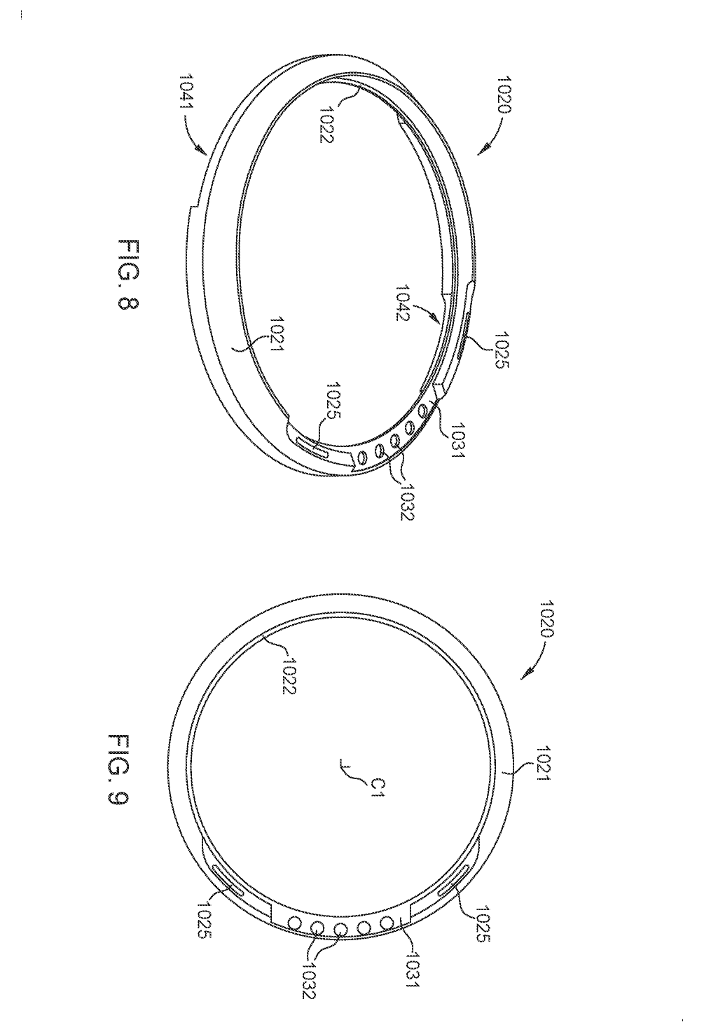

FIG. 9 is a schematic top partial view of the first liner 1020 shown in FIG. 8, according to one or more embodiments.

FIGS. 8 and 9 are described together. The first liner 1020 includes one or more inlet openings 1041 disposed on an opposite side of a radial center C1 of the liner 1020 relative to the recessed portion 1031, and one or more outlet openings 1042 disposed on the same side of the radial center C1. The one or more inlet openings 1041 can be at least part of the flow gaps through which the first gas flow F1 flows into the processing volume 136a, and the one or more outlet openings 1042 can be at least part of the exhaust gaps through which the first gas flow F1 and the second gas flow F2 is exhausted from the processing volume 136a. The one or more openings 1032 in the recessed portion 1031 of the liner 1020 are azimuthally aligned at partially between the one or more outlet openings 1042 of the liner 1020.

The first liner 1020 includes the one or more second outlet openings 1025 disposed on the same side of the radial center C1. The one or more second outlet openings 1025 are aligned (e.g., vertically) at least partially with the one or more outlet openings 1042 of the first liner 1020.

FIG. 10 is a schematic top partial view of the second liner 311 shown in FIGS. 1 and 2, according to one or more embodiments.

The second liner 311 includes one or more inlet openings 312 and one or more outlet openings 313 disposed on an opposite side of a radial center C2 of the second liner 311 relative to the one or more inlet openings 312. The one or more inlet openings 312 can be at least part of the flow gaps through which the first gas flow F1 flows into the processing volume 136a, and the one or more outlet openings 313 can be at least part of the exhaust gaps through which the first gas flow F1 and the second gas flow F2 is exhausted from the processing volume 136a. The one or more outlet openings 313 are aligned (e.g., vertically) at least partially with the one or more outlet openings 1042 of the first liner 1020. The second liner 311 includes one or more second outlet openings 314 aligned (e.g., vertically) at least partially with the one or more outlet openings 313.

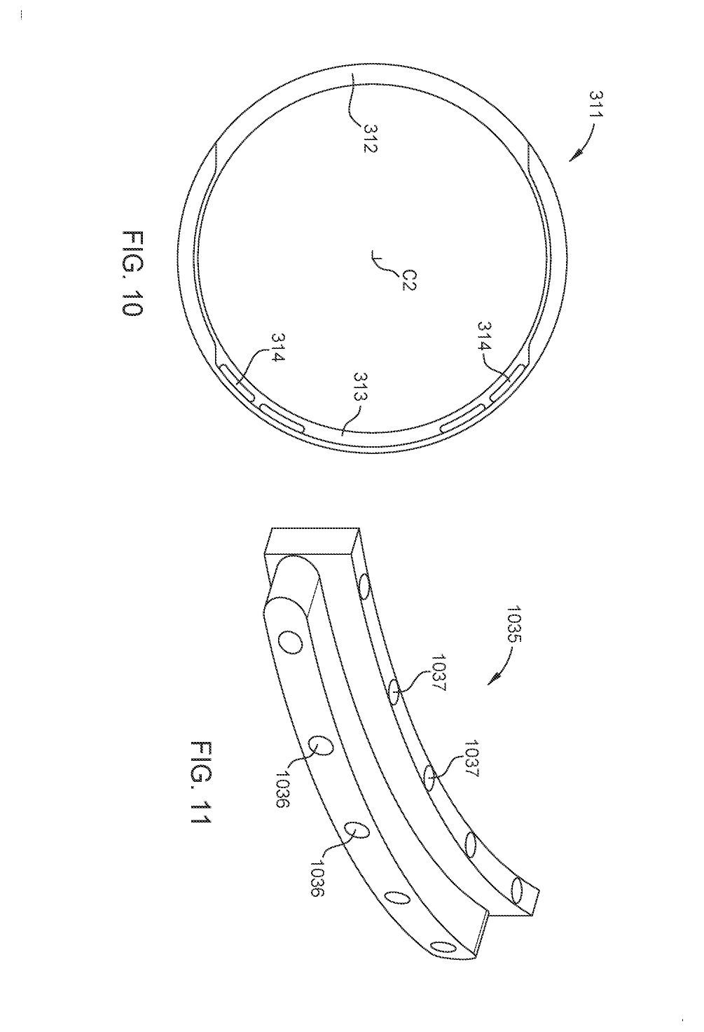

FIG. 11 is a schematic perspective partial view of an inject block 1035 shown in FIGS. 1-3, according to one or more embodiments.

The inject block 1035 includes a curved body, inlet openings 1036, and outlet openings 1037 intersecting the inlet openings 1036. The outlet openings 1037 align at least partially with the one or more inlet openings 211 of the plate apparatus 210.

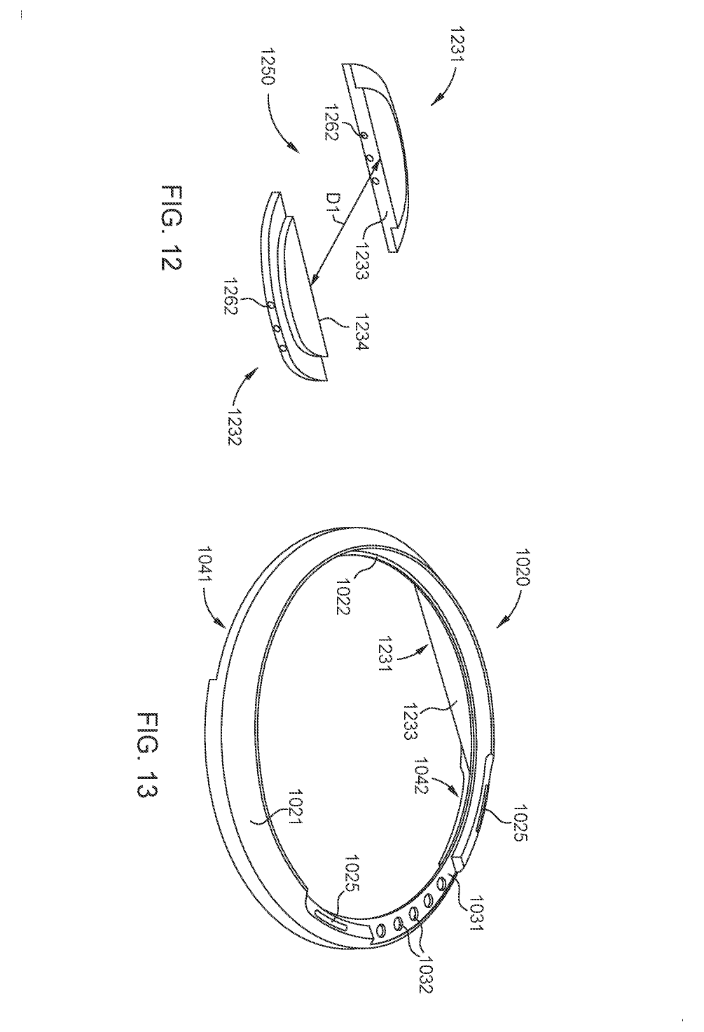

FIG. 12 is a schematic partial perspective view of part of the chamber kit 1010, according to one or more embodiments. The chamber kit 1010 includes a first flow guide block 1231 and a second flow guide block 1232 disposed opposite to one another with respect to a gas flow path for the process gas P1. The blocks 1231, 1232 are disposed in the processing volume 136a. The blocks 1231, 1232 are disposed on opposing sides of the plate apparatus 210. The blocks 12311232 can be disposed below the plate apparatus 210, and can abut against a bottom side of the first plate 215. The plate apparatus 210 and the two blocks 1231, 1232 together are part of a flow guide insert. The first flow guide block 1231 and the second flow guide block 1232 are supported on the pre-heat ring 302 disposed outwardly of the substrate support 106.

The blocks 1231, 1232 are spaced from each other along a first direction D1. In one or more embodiments, the direction D1 is perpendicular to the direction of gas flow in the processing chamber 1000 of FIG. 1 in order to guide process gas P1 within a rectangular flow opening 1250 defined between a planar inner face 1233 of the first block 1231 and a planar inner face 1234 of the second block 1232. The first flow guide block 1231 and the second flow guide block 1232 respectively include one or more opaque outer surfaces. For example, the planar inner faces 1233, 1234 can be opaque. In one or more embodiments the first block 1231 and the second block 1232 are formed of silicon carbide (SiC). The one or more opaque outer surfaces can include for example, one or more of the opaque materials described above.

It is contemplated that the first flow guide block 1231 and the second flow guide block 1232 may be omitted from the flow guide insert (as shown in FIG. 1). It is contemplated that the first and second blocks 1231, 1232 may include actuating supports configured to mechanically move the plate apparatus 210 up and down. During processing, one or more process gases (such as process gas P1 of FIG. 1) flow through the rectangular flow opening 1250 when flowing through the lower portion 136a and over the substrate 102.

As shown in FIG. 7, the blocks 1231, 1232 can include one or more flow openings 1262 (e.g., perforations) extending radially to the processing volume 136a. The openings 1262 can be omitted from the first block 731 and/or the second block 732. A third gas flow F3 of the one or more process gases P1 can flow into the processing volume 136a through the one or more flow openings 1262.

FIG. 13 is a schematic partial perspective view of the liner 1020 and blocks 1231, 1232 of the chamber kit 1010, according to one or more embodiments. In the implementation shown in FIG. 13, the blocks 1231, 1232 are coupled to the curved section 1045 of the liner 1020. In one or more embodiments, the blocks 1231, 1232 and the liner 1020 are manufactured together as a single integral part (e.g., integrally formed) of the processing chamber 1000 such that the blocks 1231, 1232 and the liner 1020 are part of the same opaque body. In one or more embodiments, the blocks 1231, 1232 are manufactured as separate bodies from the liner 1020, and the blocks 1231, 1232 are fused to the liner 1020 in a fusing operation. In one or more embodiments, the blocks 1231, 1232 are welded to the liner 1020.

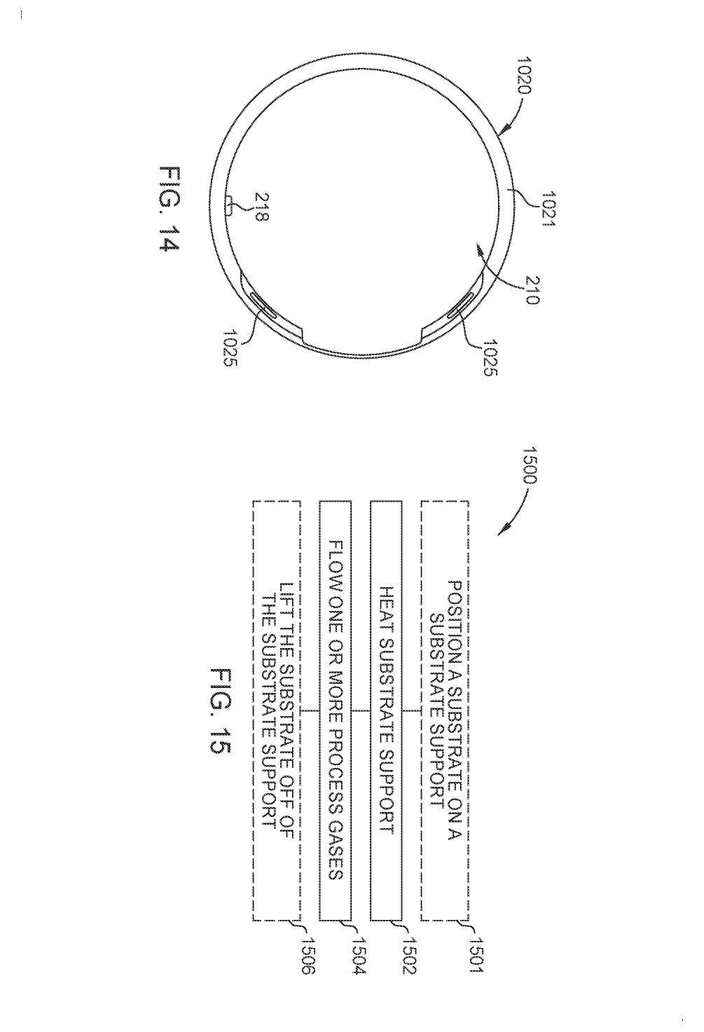

FIG. 14 is a schematic top view of the plate apparatus 210 supported on the first liner 1020, according to one or more embodiments. The plate apparatus 210 is supported on the one or more ledges 1022 and the recessed portion 1031 of the first liner 1020. In one or more embodiments, the plate apparatus 210 is fused to the blocks 1231, 1232 and/or the one or more inner ledges 1022. In one or more embodiments, the blocks 1231, 1232 and/or the one or more inner ledges 1022 are welded to the plate apparatus 210. The liner 1020 can be formed of the same material as the blocks 1231, 1232 and/or the plate apparatus 210.

FIG. 15 is a schematic block diagram view of a method 1500 of substrate processing for semiconductor manufacturing, according to one or more embodiments.

Optional operation 1501 includes positioning a substrate on a substrate support in a processing volume of a processing chamber. In one or more embodiments, the positioning includes moving a substrate support and/or a plurality of lift pins relative to each other to land the substrate on the substrate support.

Operation 1502 of the method 1500 includes heating the substrate support and/or the substrate in the processing volume to a target temperature.

Operation 1504 includes flowing one or more process gases between the substrate support and a plate apparatus (such as the plate apparatus 210) spaced from the substrate support. The one or more process gases flow over the substrate to form one or more layers on the substrate. The flow of one or more process gases can include the first gas flow F1, the second gas flow F2, and/or the third gas flow F3. The respective gas flows F1, F2, F3 can occur sequentially and/or simultaneously. The compositions of gases in the gas flows F1, F2, F3 can be the same or different with respect to each other.

Optional operation 1506 includes lifting the substrate off of the substrate support. In one or more embodiments, the lifting includes moving a substrate support and/or a plurality of lift pins relative to each other to engage the substrate with the lift pins and lift the substrate.

FIG. 16 is a schematic partial top view of a plate apparatus 1610, according to one or more embodiments. The plate apparatus 1610 includes one or more aspects, features, components, operations, and/or properties of the plate apparatus 510 shown in FIG. 5. The plate apparatus 1610 can be used in place of the plate apparatus 210 shown in FIGS. 1-4.

A plurality of flow channels 1612 are fluidly connected respectively to a plurality of inlet openings 1611 and a plurality of outlet openings 1613. The flow channels 1612 respectively include one or more curved sections to define a zig-zag path.

FIG. 17 is a schematic partial top view of a plate apparatus 1710, according to one or more embodiments. The plate apparatus 1710 includes one or more aspects, features, components, operations, and/or properties of the plate apparatus 510 shown in FIG. 5. The plate apparatus 1710 can be used in place of the plate apparatus 210 shown in FIGS. 1-4.

A plurality of flow channels 1712 are fluidly connected respectively to a plurality of inlet openings 1711 and a plurality of outlet openings 1713. The flow channels 1712 respectively include one or more curved sections to define a turnaround path such that the outlet openings 1713 are on the same side of the plate apparatus 1710 as the inlet openings 1711.

Benefits of the present disclosure include adjustability of gas flow; adjustability of gas flow patterns and velocities; adjustability of gas flow speed; adjustability of gas residence times; adjustability of flow path lengths and associated gas activation without increasing chamber sizes and footprints; various gas entry points that guide the gases to the same processing volume; and activation of a variety of gases having different activation temperatures.

Benefits also include adjustability of element (e.g., dopant) concentrations; adjustability of heat transfer; reduced diversive flow of process gases; enhanced deposition thicknesses; enhanced deposition uniformities; enhanced thermal uniformities; enhanced gas flow rate uniformities; enhanced selectivity adjustability; and increased throughput and efficiency; and reduced chamber downtime. As an example, certain gases can be reliably activated for low temperature operations (such as temperatures less than 500 degrees Celsius, for example 400 degrees Celsius or less). As another example, the second gas flow F2 can cool the plate apparatus 210, which can prevent overheating and can increase the lifespan of the plate apparatus 210.

It is contemplated that one or more aspects disclosed herein may be combined. As an example, one or more aspects, features, components, operations and/or properties of the processing chamber 1000, the plate apparatus 210, the chamber kit 1010, the plate apparatus 510, the plate apparatus 710, the first liner 1020, the second liner 311, the blocks 1231, 1232, the inject block(s) 1035, the method 1500, the plate apparatus 1610, and/or the plate apparatus 1710 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A processing chamber, comprising:
a substrate support;
one or more gas exhaust outlets on a first side of the processing volume;
a plate apparatus over the substrate support and at least partially defining a processing volume between the plate apparatus and the substrate support, the plate apparatus comprising:
one or more gas inlet openings in the plate apparatus on the first side of the processing volume,
one or more gas outlet openings in the plate apparatus on a second side of the processing volume, and
one or more gas flow channels between the one or more inlet openings and the one or more outlet openings, the one or more gas flow channels operable to flow a gas through the plate apparatus between the one or more gas inlet openings and the one or more gas outlet openings, and the one or more gas outlet openings operable to inject the gas into the processing volume on the second side to flow the gas horizontally across the processing volume and to the one or more gas exhaust outlets.

2. The processing chamber of claim 1, further comprising one or more heat sources, wherein the plate apparatus is disposed between the one or more heat sources and the substrate support, and the one or more heat sources are operable to heat the gas in the one or more gas flow channels prior to the gas flowing into the processing volume.

3. The processing chamber of claim 1, further comprising:
a first flow guide block disposed in the processing volume; and
a second flow guide block disposed opposite the first flow guide block with respect to a gas flow path in the processing volume, the first flow guide block and the second flow guide block respectively comprising one or more opaque outer surfaces.

4. The processing chamber of claim 3, wherein the first flow guide block and the second flow guide block define a rectangular flow opening between a first planar inner face of the first flow guide block and a second planar inner face of the second flow guide block.

5. The processing chamber of claim 1, wherein the plate apparatus further comprises one or more second gas outlet openings extending between the one or more gas flow channels and the processing volume.

6. The processing chamber of claim 3, wherein the first flow guide block and the second flow guide block are supported on a pre-heat ring disposed outwardly of the substrate support.

7. The processing chamber of claim 3, wherein the first flow guide block and the second flow guide block are coupled to a curved section of a liner disposed outwardly of the plate apparatus, and the first flow guide block and the second flow guide block are fused to or integrally formed with the curved section of the liner.

8. The processing chamber of claim 3, wherein one or more of the first flow guide block or the second flow guide block comprises one or more gas flow channels extending radially to the processing volume.

9. A plate apparatus, comprising:
a first plate comprising one or more inlet openings and one or more outlet openings therein; and
a second plate sized and shaped for disposition on the first plate to define one or more flow channels between the first plate and the second plate, the first plate and the second plate respectively comprising opaque particles suspended in transparent quartz.

10. The plate apparatus of claim 9, wherein the one or more flow channels extend horizontally between the one or more inlet openings and the one or more outlet openings.

11. The plate apparatus of claim 9, further comprising a locating opening in an outer edge of the plate apparatus.

12. The plate apparatus of claim 9, wherein the one or more flow channels comprise a first set of flow channels in the first plate and a second set of flow channels in the second plate, wherein the first set of flow channels and the second set of flow channels are disposed in an alternating arrangement.

13. The plate apparatus of claim 9, further comprising one or more second outlet openings extending between the one or more flow channels and the processing volume.

14. The plate apparatus of claim 9, wherein the one or more inlet openings of the plate apparatus are in a flange section of the plate apparatus.

15. A chamber kit comprising:
the plate apparatus of claim 8; and
a liner comprising:
one or more ledges sized and shaped to support an outer region of the plate apparatus,
a recessed portion, and
one or more openings in the recessed portion, the one or more openings sized and shaped to at least partially align with the one or more inlet openings of the plate apparatus, wherein the one or more ledges of the liner are disposed radially inwardly of the recessed portion.

16. The chamber kit of claim 15, wherein the one or more inlet openings of the plate apparatus are in a flange section of the plate apparatus, and the flange section is sized and shaped to extend over the recessed portion of the liner.

17. The chamber kit of claim 15, wherein the liner further comprises:
one or more inlet openings disposed on an opposite side of a radial center of the liner relative to the recessed portion;
one or more outlet openings disposed on the same side of the radial center; and
one or more second outlet openings disposed on the same side of the radial center, the one or more second outlet openings aligned at least partially with the one or more outlet openings of the liner.

18. A method of substrate processing, comprising:
heating a substrate support in a processing volume of a processing chamber; and
flowing one or more process gases between the substrate support and a plate apparatus spaced from the substrate support, the flowing of the one or more process gases comprising:
flowing a first gas flow through a sidewall of the processing chamber on an inject side of the processing volume, into the processing volume, and over a substrate positioned on the substrate support,
flowing a second gas flow through the sidewall of the processing chamber on an exhaust side of the processing volume,
flowing the second gas flow through the plate apparatus from the exhaust side and to the inject side, and
flowing the second gas flow out of the plate apparatus and into the processing volume on the inject side, and over the substrate.

19. The method of claim 18, wherein the plate apparatus comprises:
one or more inlet openings,
one or more outlet openings, and
one or more flow openings between the one or more inlet openings and the one or more outlet openings.

20. The method of claim 19, wherein the one or more flow openings include a plurality of flow openings spaced from each other, and the plurality of flow openings are in fluid communication with a single inlet opening of the one or more inlet openings.
